(19) United States
(12) Patent Application Publication
(10) Pub. No.: US 2020/0154602 A1
(43) Pub. Date: May 14, 2020

(54) TANK AND COOLING SYSTEM

(71) Applicant: FUJITSU LIMITED, Kawasaki-shi (JP)

(72) Inventors: Shingo YAMAGUCHI, Kawasaki (JP); Satoshi Kanbayashi, kawasaki (JP); Hayato Shida, Kawasaki (JP); MAMI NAKADATE, Yokohama (JP); Kanako IMAI, Sagamihara (JP); Yukari Sato, inagi (JP)

(73) Assignee: FUJITSU LIMITED, Kawasaki-shi (JP)

(21) Appl. No.: 16/600,602

(22) Filed: Oct. 14, 2019

(30) Foreign Application Priority Data
Nov. 8, 2018 (JP) 2018-210501

(51) Int. Cl. H05K 7/20

(52) U.S. Cl. CPC H05K 7/20272

(57) ABSTRACT

A tank includes: a first housing configured to include a first inner surface and a first peripheral edge projecting from the first inner surface; a second housing configured to include a second inner surface and a second peripheral edge, the second inner surface facing the first inner surface, the second peripheral edge projecting from the second inner surface and facing the first peripheral edge; and a sticky elastic body inside the first and second peripheral edge, wherein the first peripheral edge has a first inclined surface inclined from inside to outside from the first inner surface toward a first projecting end of the first peripheral edge, the second peripheral edge has a second inclined surface inclined from inside to outside from the second inner surface toward a second projecting end of the second peripheral edge, and the elastic body is stuck to the first and second inclined surface.

### CROSS-REFERENCE TO RELATED APPLICATION

This application is based upon and claims the benefit of priority of the prior Japanese Patent Application No. 2018-210501, filed on Nov. 8, 2018, the entire contents of which are incorporated herein by reference.

### FIELD

The embodiments discussed herein are related to a tank and a cooling system.

### BACKGROUND

There has been a hermetically sealed container in which a pair of housing members are combined through an O-ring by use of screwing or the like means, and a charge-coupled device (CCD) element and a cooling element for cooling it and the like are accommodated in the inside thereof. There has been a cooler in which a pair of heat radiating bodies are combined by fitting of their fitting sections to each other through a seal member such as a seal ring made of an elastic body, and a refrigerant flow path is formed in the inside thereof.

Examples of the related art include Japanese Laid-open Patent Publication No. 06-120469 and Japanese Laid-open Patent Publication No. 2011-198822.

### SUMMARY

According to an aspect of the embodiment, a tank includes: a first housing configured to include a first inner surface and a first peripheral edge section projecting from the first inner surface; a second housing configured to include a second inner surface and a second peripheral edge section, the second inner surface facing the first inner surface, the second peripheral edge section projecting from the second inner surface and facing the first peripheral edge section; and a sticky elastic body provided inside the first peripheral edge section and the second peripheral edge section facing each other, wherein the first peripheral edge section has a first inclined surface that is inclined from inside to outside from the first inner surface toward a first projecting end of the first peripheral edge section, the second peripheral edge section has a second inclined surface that is inclined from inside to outside from the second inner surface toward a second projecting end of the second peripheral edge section, and the elastic body is stuck to the first inclined surface and the second inclined surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1C are figures depicting an example of a tank according to a first embodiment;

FIG. 2 is a figure depicting an example of a cooling system according to a second embodiment;

FIG. 3 is a figure (No. 1) illustrating an example of a tank according to the second embodiment;

FIG. 4 is a figure (No. 2) illustrating an example of a tank according to the second embodiment;

FIG. 5 is a figure (No. 3) illustrating an example of a tank according to the second embodiment;

FIGS. 6A and 68 are figures (No. 1) illustrating an example of an assembling method for a tank according to the second embodiment;

FIGS. 7A and 7B are figures (No. 2) illustrating an example of an assembling method for a tank according to the second embodiment;

FIGS. 8A and 8B are figures (No. 3) illustrating an example of an assembling method for a tank according to the second embodiment;

FIGS. 9A and 9B are figures illustrating an example of use status of the tank according to the second embodiment;

FIGS. 10A and 10B are figures illustrating an example of use status of a tank according to another embodiment;

FIGS. 11A and 11B are figures depicting examples of a tank according to further embodiments;

FIG. 12 is a figure illustrating a simulation model of a tank;

FIGS. 13A to 13C are figures (No. 1) depicting an example of simulation results of a tank;

FIGS. 14A to 14C are figures (No. 2) depicting an example of simulation result of a tank;

FIGS. 15A to 15C are figures (No. 3) depicting an example of simulation results of a tank; and

FIGS. 16A to 16C are figures (No. 4) depicting an example of simulation results of a tank.

### DESCRIPTION OF EMBODIMENTS

In a tank adopting a structure in which a pair of housings are combined together through a seal member, a sufficient sealing property may not be maintained, depending on the use status, and such a substance as a refrigerant stored in the inside of the tank may leak out.

In an aspect, it is an object of the embodiments discussed herein to realize a tank capable of suppressing leakage.

### First Embodiment

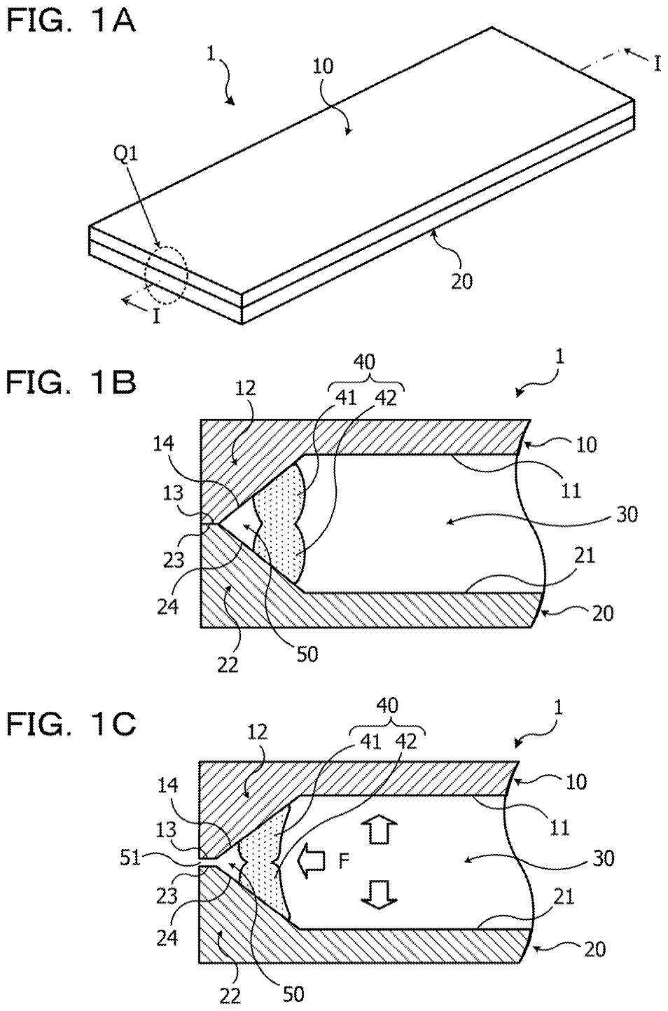

FIGS. 1A to 1C are figures depicting an example of a tank according to a first embodiment. FIG. 1A depicts a perspective schematic view of a major part of an example of the tank. FIG. 1B is an enlarged sectional schematic view of part Q1 of I-I section of FIG. 1A. FIG. 1C is an enlarge sectional schematic view of part Q1 for illustrating an example of use status of the tank.

First, the configuration of the tank will be described referring to FIGS. 1A and 1B.

As depicted in FIGS. 1A and 1B, the tank 1 includes a set of a housing 10 and a housing 20 which are combined together.

A resin material, for example, is used for the housing 10 and the housing 20. Examples of the resin material to be used for the housing 10 and the housing 20 include epoxy resins, polyamide resins, phenolic resins, acaylonitrile-butadiene-styrene (ABS) resins, and polyester resins, and resin materials with fibers such as glass fibers and carbon fibers contained in these resins, for example, so-called fiber-reinforced plastic (FRP). In place of these resin materials or together with these resin materials, various materials such as metallic materials, ceramic materials, and glass materials may be used for the housing 10 and the housing 20. The same kind of material may be used, or different materials may be used, for the housing 10 and the housing 20.

As depicted in FIG. 18, the housing 10 includes an inner surface 11, and a peripheral edge section 12 projecting from the inner surface 11. As Illustrated in FIG. 1B, the housing 20 includes an inner surface 21 facing the inner surface 11 of the housing 10, and a peripheral edge section 22 projecting from the inner surface 21 and facing the peripheral edge section 12 of the housing 10. The housing 10 and the housing 20 are combined together, in such a manner that the inner surface 11 and the inner surface 21 face each other, and a projecting end 13 of the peripheral edge section 12 and a projecting end 23 of the peripheral edge section 22 face each other, to thereby form the tank 1.

The housing 10 and the housing 20 combined together as depicted in FIGS. 1A and 18 are fixed by a technique such as screwing (not illustrated). The housing 10 and the housing 20 may be fixed by a technique such as adhesion, welding, and fusion bonding, in place of or together with the screwing.

Various substances (not illustrated), for example, a liquid substance is stored in an inside 30 (FIG. 18) between the housing 10 and the housing 20 combined together as depicted in FIGS. 1A and 1B. Other than the liquid substance, a gaseous substance may be stored in the inside 30 of the tank 1. In the inside 30 of the tank 1, a liquid and a gas may coexist, a solid and a liquid may coexist, a solid and a gas may coexist, or a solid and a liquid and a gas may coexist.

As depicted in FIG. 1B, the peripheral edge section 12 of the housing 10 is provided with an inclined surface 14 inclined from inside to outside from the inner surface 11 to the projecting end 13 of the peripheral edge section 12. As illustrated in FIG. 1B, the peripheral edge section 22 of the housing 20 is provided with an inclined surface 24 inclined from inside to outside from the inner surface 21 toward the projecting end 23 of the peripheral edge section 22. The housing 10 and the housing 20 are combined together, and the peripheral edge section 12 (its projecting end 13) and the peripheral edge section 22 (Its projecting end 23) are made to face each other, whereby the inclined surface 14 and the inclined surface 24 are made to face each other.

As depicted in FIG. 18B, the tank 1 further includes an elastic body 40 provided inside the peripheral edge section 12 of the housing 10 and the peripheral edge section 22 of the housing 20 that face each other.

Various materials used as a sealing material are used for the elastic body 40. Examples of the material to be used for the elastic body 40 include a hot-melt type sealing material using a thermoplastic resin. The elastic body 40 has a sticking property. The sticking property is, for example, such that when the elastic body 40 is placed on a substrate, it would not easily fall off, but it is easily released from the substrate by a given force. Further, a material having a flexibility and having a low hardness, for example, an extra low hardness, is used for the elastic body 40. The extra low hardness is such that a compressibility is 30% and a surface pressure is equal to or less than 0.01 MPa. The elastic body 40 depicted in FIG. 1B is disposed inside the peripheral edge section 12 and the peripheral edge section 22, for example, in such a state that an elastic body 41 stuck to the housing 10 side and an elastic body 42 stuck to the housing 20 side are further stuck to each other and unified with each other.

A given substance is stored in the inside 30 surrounded by the housing 10 and the housing 20 and the elastic body 40 (the elastic body 41 and the elastic body 42 in the stuck state). As illustrated in FIG. 1B, a space 50 is present between the elastic body 40 and the projecting end 13 of the peripheral edge section 12 and the projecting end 23 of the peripheral edge section 22 that face each other, for example, outside of the elastic body 40.

An example of use status of the tank will be described below, referring to FIG. 1C.

In the tank 1 configured as above, for example, due to the storage of the substance stored in the inside 30 or due to a rise in the pressure of the substance stored in the inside 30, forces F act from inside toward outside as indicated by large-width arrows in FIG. 1C. In the tank 1, when such forces F act, the elastic body 40 is pushed from the inside 30, and while the elastic body 41 and the elastic body 42 remain in a stuck state, they are deformed on the inclined surface 14 of the peripheral edge section 12 and the inclined surface 24 of the peripheral edge section 22 toward the projecting end 13 and the projecting end 23 of the latter. This deformation may be accompanied by a movement (displacement from an initial position) of the elastic body 40 toward the projecting end 13 and the projecting end 23. Since both the peripheral edge section 12 and the peripheral edge section 22 have the inclined surface 14 and the inclined surface 24 on inside, the spacing between the inclined surface 14 and the inclined surface 24 is narrowed in approaching the projecting end 13 and the projecting end 23 facing each other. Therefore, the elastic body 40 pushed from inside by the forces F is deformed in such a manner as to fill the space 50 surrounded by the elastic body 40 and the inclined surface 14 and the inclined surface 24, while the elastic body 41 and the elastic body 42 constituting the elastic body 40 are not liable to be peeled off from each other but remain in the stuck state.

In the tank 1, since the elastic body 40 is thus deformed by the forces F acting from inside in such a manner as to fill the space 50 on the outside thereof while remaining in the stuck state, the sealing property at the peripheral edge section 12 and the peripheral edge section 22 facing each other is maintained. Accordingly, the substance stored in the inside 30 is suppressed from leaking into the space 50 outside of the elastic body 40, or leaking to the exterior of the tank 1. For example, even if a gap 51 is generated between the projecting end 13 of the peripheral edge section 12 and the projecting end 23 of the peripheral edge section 22 as depicted in FIG. 1C, the substance stored in the inside 30 is suppressed from leaking to the exterior of the tank 1.

According to the first embodiment, the tank 1 capable of effectively suppressing the substance stored in the inside 30 from leaking to the exterior is realized.

### Second Embodiment

Here, examples of a cooling system for an electronic device and a tank used therefor will be described as a second embodiment.

First, the cooling system will be described.

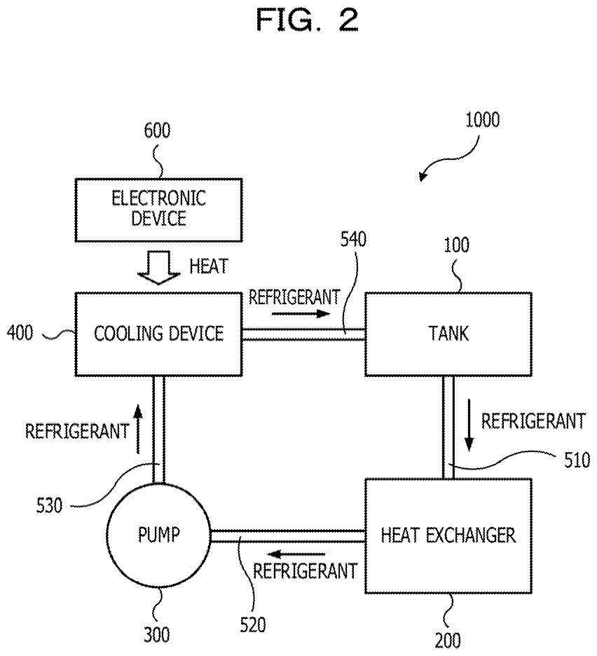

FIG. 2 is a figure depicting an example of a cooling system according to the second embodiment.

A cooling system 1000 depicted in FIG. 2 includes a tank 100, a heat exchanger 200, a pump 300, and a cooling device 400. The tank 100 and the heat exchanger 200, the heat exchanger 200 and the pump 300, the pump 300 and the cooling device 400, and the cooling device 400 and the tank 100, are intercoupled by a piping 510, a piping 520, a piping 530, and a piping 540, respectively. The piping 510, the piping 520, the piping 530, and the piping 540 may be equipped with various apparatuses (not illustrated) such as valves and flowmeters.

An electronic device 600 is thermally coupled to the cooling device 400 of the cooling system 1000. A device or apparatus that generates heat attendant on operation, such as a semiconductor device, for example, a semiconductor chip or a semiconductor package, and a device or apparatus in which such a semiconductor device is used, is used for the electronic device 600.

A device provided with a flow path (refrigerant flow path) in which a liquid refrigerant such as an antifreezing fluid for cooling the electronic device 600 flows is used as the cooling device 400. For example, a device in which a hole or a groove or a pipe for serving as a refrigerant flow path is formed in a thermal conductor such as a heat sink, a device in which a pipe for serving as a refrigerant flow path is thermally coupled to the outside of a thermal conductor such as a heat sink, or the like is used as the cooling device 400. Other than these, a cooling device which includes a tank storing therein a given amount of a refrigerant and in which the electronic device 600 is immersed in the tank, for example, a so-called liquid immersion type cooling device may be used as the cooling device 400.

A refrigerant is introduced into the cooling device 400 from the pump 300 through the piping 530. The refrigerant thus introduced is made, for example, to flow through the above-mentioned refrigerant flow path of the cooling device 400, during when it deprive heat generated from the electronic device 600 thermally coupled to the cooling device 400, and is discharged to the exterior of the cooling device 400. Alternatively, the refrigerant introduced is, for example, temporarily stored in a given amount in the above-mentioned tank (liquid immersion tank) of the cooling device 400, deprives heat generated from the electronic device 600 mounted (immersed) in the tank, and is discharged to the exterior of the cooling device 400.

The refrigerant warmed by depriving the heat generated by the electronic device 600 and discharged to the exterior of the cooling device 400 is introduced into the tank 100 through the piping 540. The refrigerant introduced into the tank 100 is temporarily stored in a given amount in the tank 100, and is discharged to the exterior of the tank 100.

The refrigerant discharged out of the tank 100 is introduced into the heat exchanger 200 through the piping 510. The refrigerant thus introduced is made to flow in the heat exchanger 200, during when it is cooled, and the cooled refrigerant is discharged to the exterior of the heat exchanger 200.

The refrigerant discharged to the outside of the heat exchanger 200 is introduced into the pump 300 through the piping 520 (for example, the pump 300 takes in the refrigerant by sucking-in or sucking-up). The pump 300 takes in the refrigerant cooled in the heat exchanger 200 through the piping 520, and sends the refrigerant to the cooling device 400 through the piping 530. In the cooling device 400, the refrigerant sent from the pump 300 (the refrigerant cooled by the heat exchanger 200) is used, to cool the electronic device 600.

In the cooling system 1000, the refrigerant is thus circulated through the cooling device 400, the tank 100, and the heat exchanger 200 by the pump 300, whereby cooling of the electronic device 600 is performed.

For example, the cooling system 1000 as above-described is adopted as a cooling system for cooling the electronic device 600 installed in a communication base station or a small communication base station. As a technique for cooling the electronic device 600 installed in a communication base station, there is a technique in which air conditioning is utilized, but this technique may have a problem in a case where it is difficult to obtain a sufficient cooling effect or a sufficient cooling efficiency for the heat generation of the electronic device, or a problem that noise matters. In view of this, for cooling of the electronic device 600 installed in a communication base station or the like, the above-described cooling system 1000 utilizing the liquid refrigerant such as an antifreezing fluid as a circulating refrigerant may be adopted, such as to enhance cooling efficiency and reducing noise.

The structure of the tank 100 used in the cooling system 1000 will be described below.

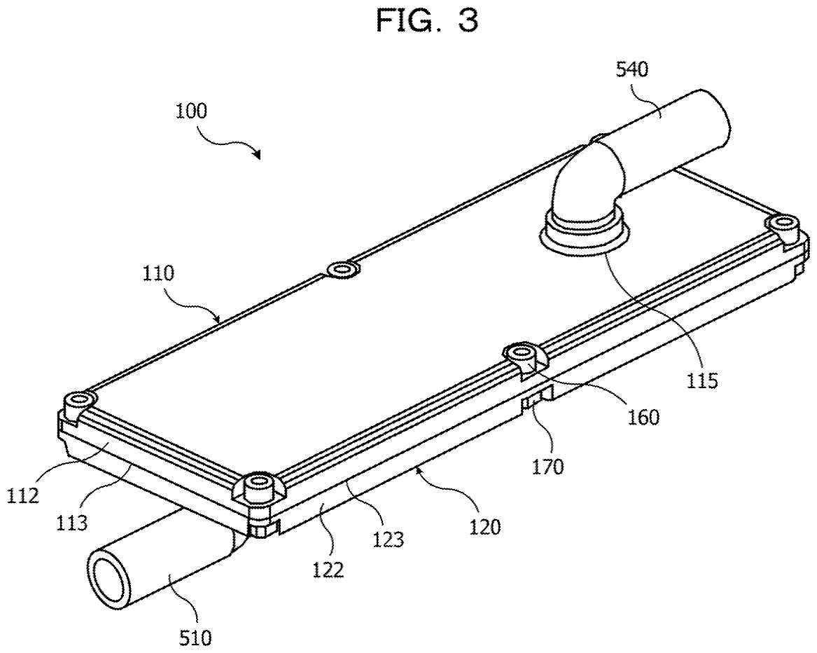

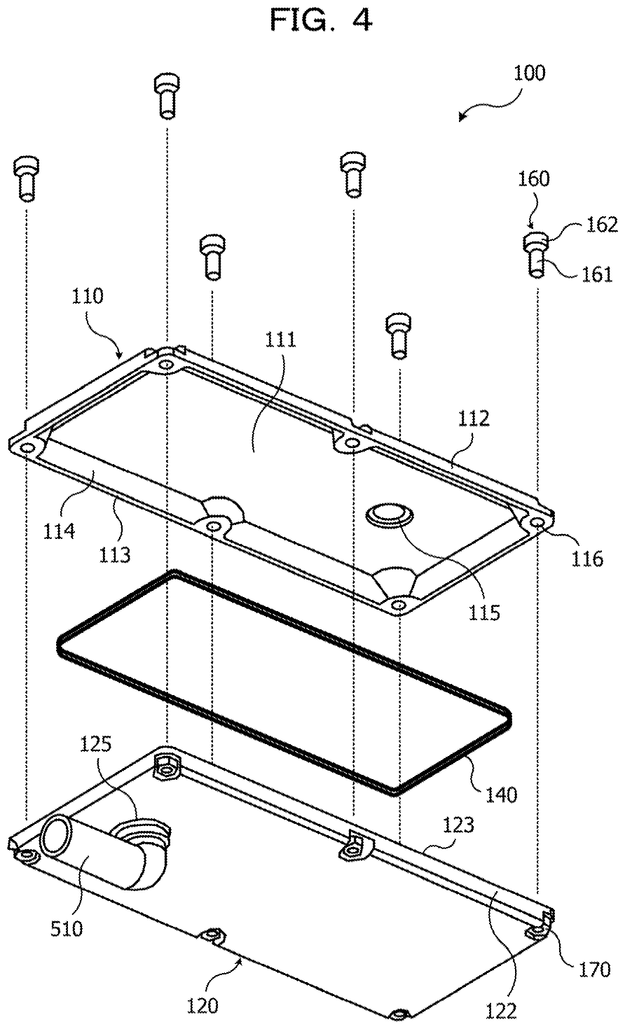

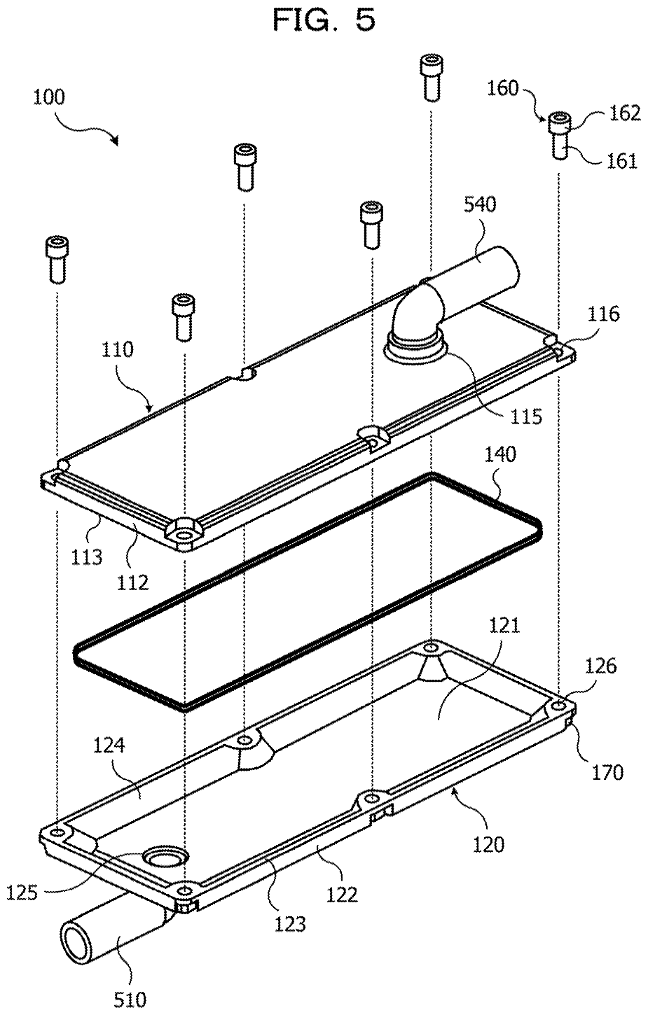

FIGS. 3 to 5 are illustrations of an example of a tank according to the second embodiment. FIG. 3 depicts a perspective schematic view of a major part of an example of the tank. FIG. 4 depicts an exploded perspective schematic view of a major part of the example of the tank as viewed from one side. FIG. 5 depicts an exploded perspective schematic view of a major part of the example of the tank as viewed from the other side.

As illustrated in FIGS. 3 to 5, the tank 100 includes a set of a housing 110 and a housing 120 which are combined with each other. The housing 110 is provided with a refrigerant introduction port 115 to which the piping 540 intercoupling the housing 110 and the cooling device 400 is coupled. The housing 120 is provided with a refrigerant discharge port 125 to which the piping 510 intercoupling the housing 120 and the heat exchanger 200 is coupled. A resin material, for example, is used for the housing 110 and the housing 120. Examples of the resin material to be used for the housing 110 and the housing 120 include epoxy resin, polyamide resins, phenolic resins, ABS resins, polyester resins and the like, and resin materials in which glass fibers, carbon fibers or the like are contained in these resins, for example, so-called FRP. The same kind of material may be used, or different kinds of materials may be used, for the housing 110 and the housing 120.

As depicted in FIG. 4, the housing 110 includes an inner surface 111, and a peripheral edge section 112 projecting from the inner surface 111. As Illustrated in FIG. 5, the housing 120 includes an inner surface 121 facing the inner surface 111 of the housing 110, and a peripheral edge section 122 projecting from the inner surface 121 and facing the peripheral edge section 112 of the housing 110. The housing 110 and the housing 120 are combined with each other in such a manner that their inner surface 111 and inner surface 121 face each other, and an projecting end 113 of the peripheral edge section 112 and a projecting end 123 of the peripheral edge section 122 face each other, whereby the tank 100 as depicted in FIG. 3 is formed.

As illustrated in FIG. 4, the peripheral edge section 112 of the housing 110 is provided with an inclined surface 114 inclined from inside to outside from the inner surface 111 toward the projecting end 113 of the peripheral edge section 112. As depicted in FIG. 5, the peripheral edge section 122 of the housing 120 is provided with an inclined surface 124 inclined from inside to outside from the inner surface 121 toward the projecting end 123 of the peripheral edge section 122. With the housing 110 and the housing 120 combined with each other, and with the peripheral edge section 112 (its projecting end 113) and the peripheral edge section 122 (its projecting end 123) made to face each other, the inclined surface 114 and the inclined surface 124 are made to face each other.

As depicted in FIGS. 4 and 5, the tank 100 further includes an elastic body 140 provided inside the peripheral edge section 112 of the housing 110 and the peripheral edge section 122 of the housing 120 that face each other. The elastic body 140 has at least part thereof disposed at the positions of the inclined surface 114 of the peripheral edge section 112 and the inclined surface 124 of the peripheral edge section 122.

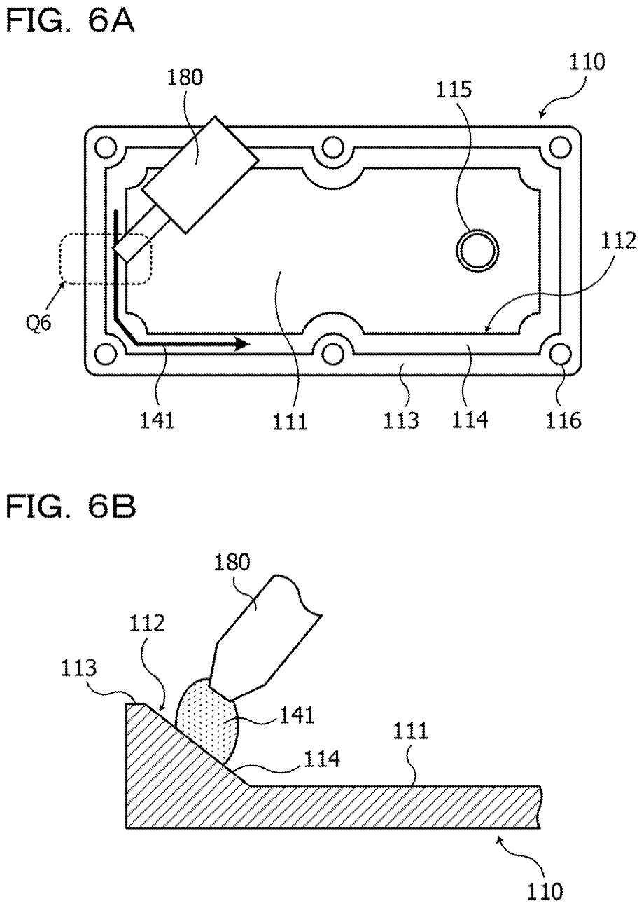

Various materials used as a sealing material are used for the elastic body 140. Examples of the material to be used for the elastic body 140 include a hot-melt type sealing material using a thermoplastic resin. The elastic body 140 has a sticking property. Here, the sticking property is such a property that when the housing 110 and the housing 120 is coated with the material at the time of assembly (FIGS. 6 to 8) described later the material does not fall off easily, but, after the coating, the material is easily peeled off from the housing 110 and the housing 120 with a given force. Further, the elastic body 140 has flexibility, and an extra low hardness material is used. Here, the extra low hardness is a hardness such that the compressibility is 30% and the surface pressure is equal to or less than 0.01 MPa. The elastic body 140 is disposed such that when the housing 110 and the housing 120 are combined with each other, elastic bodies (elastic bodies 141 and 142) applied to the housing 110 side and the housing 120 side as described later are disposed while stuck to the inside (the inclined surface 114 and the inclined surface 124) of the peripheral edge section 112 and the peripheral edge section 122, in the state of being stuck to each other and unified with each other.

As depicted in FIGS. 4 and 5, the housing 110 and the housing 120 combined with each other are fixed at plural locations (in this example, six locations) of their peripheral edge section 112 and peripheral edge section 122 by use of screw 160 and nuts 170, in a state in which the elastic body 140 is disposed inside the peripheral edge section 112 and the peripheral edge section 122. For example, holes 116 sized such that shaft portions 161 of the screws 160 are inserted and head portions 162 of the screws 160 are seated are provided on the side of the housing 110 on one side. Holes 126 sized such that the head portions 161 of the screws 160 are inserted are provided on the side of the housing 120 on the other side. Of the screws 160, the shaft portions 161 are inserted from the housing 110 side into the holes 116 thereof and further into the holes 126 of the housing 120, while the head portions 162 are seated on the housing 110, and, on the housing 120 side, the shaft portions 161 are engaged with the nuts 170 including screw grooves corresponding to the screw threads of the shaft portions 161. As a result, the housing 110 and the housing 120 are fixed by use of the screws 160 and the nuts 170.

In the tank 100, a liquid refrigerant such as an antifreezing fluid is stored in the inside surrounded by the housing 110 and the housing 120 combined with each other with the peripheral edge section 112 and the peripheral edge section 122 facing each other and by the elastic body 140 disposed in a stuck state inside the peripheral edge section 112 and the peripheral edge section 122. The refrigerant is introduced through the introduction port 115 coupled with the piping 540, is stored in the inside of the tank 100, and is discharged through the discharge port 125 coupled with the piping 510.

An assembling method for the tank 100 will be described below.

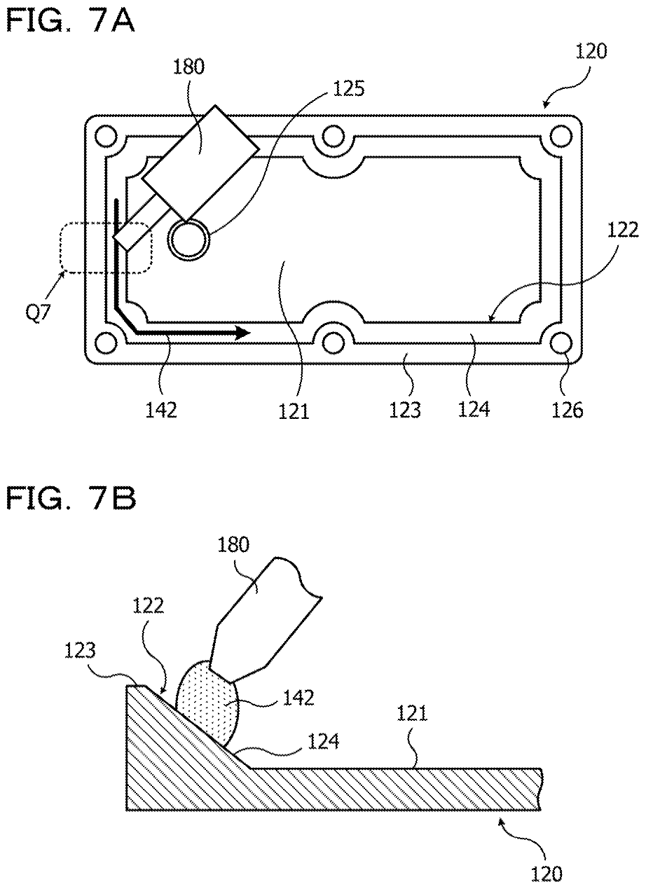

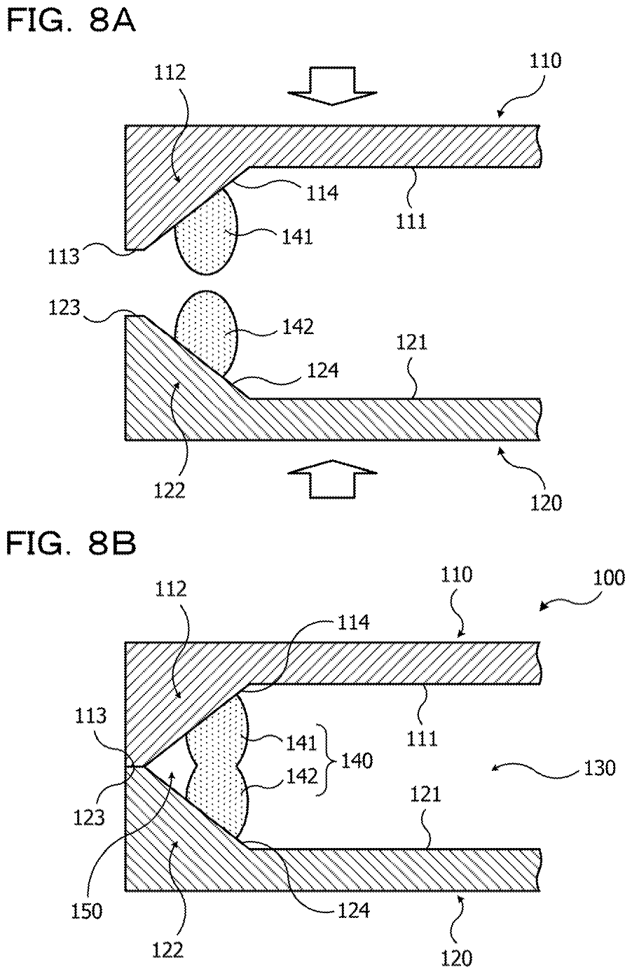

FIGS. 6 to 8 are figures illustrating an example of a method of assembling a tank according to the second embodiment. FIG. 6A depicts a schematic plan view of a major part of an example of a process of supplying the elastic body to the housing on one side. FIG. 6B depicts an enlarged sectional schematic view of part Q6 of FIG. 6A. FIG. 7A depicts a schematic plan view of a major part of an example of a process of supplying the elastic body to the housing on the other side. FIG. 7B depicts an enlarged sectional schematic view of part Q7 of FIG. 6A. FIG. 8A depicts a sectional schematic view of a major part of an example of a process of disposing the set of housings. FIG. 8B depicts a sectional schematic view of a major part of an example of a process of coupling the set of housings.

FIG. 6A schematically depicts a flat surface of the housing 110 on one side of the tank 100 as viewed from the inner surface 111 side, and FIG. 6B schematically depicts in an enlarged form a section of part Q6. As illustrated in FIGS. 6A and 6B, the peripheral edge section 112 projecting from the inner surface 111 is provided, and the peripheral edge section 112 is provided with the inclined surface 114 inclined from inside to outside from the inner surface 111 toward the projecting end 113 of the peripheral edge section 112.

At the time of assembling the tank 100, a sealing material provided with fluidity by heating or the like is applied to the inclined surface 114 of the peripheral edge section 112 of the housing 110 using a supply device 180 such as a dispenser, to form the elastic body 141 (part of the elastic body 140). For example, the supply device 180 is moved in the manner of going round the inner surface 111 of the housing 110 (illustrated by adding an arrow for convenience of explanation to the elastic body 141 of FIG. 6A), to form the elastic body 141 on the inclined surface 114 of the peripheral edge section 112. For example, a thermoplastic resin which has a sticking property and a flexible property and from which an extra low hardness elastic body 141 may be obtained is used as the sealing material. As the sealing material of the elastic body 141, one that has a certain degree of viscosity such that it sticks to the inclined surface 114 to which it is applied and at least part thereof remains on the inclined surface 114 during assembly of the tank 100, or one that is conditioned to have such a degree of viscosity, is used. The sealing material of the elastic body 141 is applied to the inclined surface 114 by use of the supply device 180 at a position such that it sticks to the inclined surface 114 and at least part thereof remains on the inclined surface 114 during the assembly of the tank 100. The sealing material of the elastic body 141 provided on the inclined surface 114 of the housing 110 is applied by use of the supply device 180 to a position corresponding to the sealing material of the elastic body 142 provided on the inclined surface 124 of the housing 120 as described later.

FIG. 7A schematically depicts a flat surface of the housing 120 on the other side of the tank 100 as viewed from the inner surface 121 side, and FIG. 7B schematically depicts in an enlarged from a section of part Q7. As illustrated in FIGS. 7A and 78, the housing 120 is provided with the peripheral edge section 122 projecting from the inner surface 121, and the peripheral edge section 122 is provided with the inclined surface 124 inclined from inside to outside from the inner surface 121 toward the projecting end 123 of the peripheral edge section 122.

At the time of assembling the tank 100, a sealing material provided with fluidity by heating or the like is applied to the inclined surface 124 of the peripheral edge section 122 of the housing 120 using the supply device 180 such as a dispenser, to form the elastic body 142 (part of the elastic body 140). For example, the supply device 180 is moved in the manner of going round the inner surface 121 of the housing 120 (Illustrated by adding an arrow for convenience of explanation to the elastic body 142 of FIG. 7A), to form the elastic body 142 on the inclined surface 124 of the peripheral edge section 122. For example, a thermoplastic resin which has a sticking property and a flexible property and from which an extra low hardness elastic body 142 may be obtained is used as the sealing material. As the sealing material of the elastic body 142, one that has a certain degree of viscosity such that it sticks to the inclined surface 124 to which it is applied and at least part thereof remains on the inclined surface 124 during assembly of the tank 100, or one that is conditioned to have such a degree of viscosity, is used. The sealing material of the elastic body 142 is applied to the inclined surface 124 by use of the supply device 180 to a position such that it sticks to the inclined surface 124 and at least part thereof remains on the inclined surface 124 during the assembly of the tank 100. The sealing material of the elastic body 142 provided on the inclined surface 124 of the housing 120 is applied to by use of the supply device 180 to a position corresponding to the sealing material of the elastic body 141 provided on the inclined surface 114 of the housing 110.

The housing 110 (FIG. 6) and the housing 120 (FIG. 7) prepared in the above-mentioned manner are disposed in such a manner that their inner surface 111 and inner surface 121 face each other, and the peripheral edge section 112 (its projecting end 113) and the peripheral edge section 122 (Its projecting end 123) face each other, as depicted in FIG. 8A. The housing 110 and the housing 120 are pressed in such a manner that the projecting end 113 of the peripheral edge section 112 and the projecting end 123 of the peripheral edge section 122 contact (or come close to, in this example, contact) each other. For example, where the elastic body 141 and the elastic body 142 show a sufficient sticking property under the temperature at the time of assembly, this pressing is conducted under the temperature, whereas where they do not show a sufficient sticking property at the temperature, the pressing is conducted with melting or softening by heating.

With the housing 110 and the housing 120 pressed, the projecting end 113 of the peripheral edge section 112 and the projecting end 123 of the peripheral edge section 122 are made to contact each other, and their elastic body 141 and elastic body 142 are made to contact each other and stick to each other, as depicted in FIG. 8B. As a result, there is obtained a state in which the housing 110 and the housing 120 are combined with each other while the elastic body 140 composed of the elastic body 141 and the elastic body 142 stuck together is disposed inside the peripheral edge section 112 and the peripheral edge section 122 which face each other. In this state, the housing 110 and the housing 120 are fixed by use of the screw 160 and the nuts 170 as above-mentioned, whereby the tank 100 is assembled.

After the housing 110 and the housing 120 are combined with each other, or after they are further fixed by use of the screws 160 and the nuts 170, heating at such a temperature that the elastic body 141 and the elastic body 142 are melted or softened may be performed. With such a heating, the elastic body 140 in which the elastic body 141 and the elastic body 142 are sufficiently stuck to each other or unified with each other is obtained.

For example, the tank 100 is assembled by the method as depicted in FIGS. 6A and 68, FIGS. 7A and 7B, and FIGS. 8A and 8B.

In the tank 100 thus assembled, a refrigerant is stored in the inside 130 depicted in FIG. 8B that is surrounded by the housing 110, the housing 120, and the elastic body 140 disposed inside their peripheral edge section 112 and inner peripheral edge section 122. In the tank 100, the space 150 is formed between the elastic body 140 and the projecting end 113 of the peripheral edge section 112 and the projecting end 123 of the peripheral edge section 122 (outside of the elastic body 140), as illustrated in FIG. 8B.

A status in which the tank 100 is used in the cooling system 1000 will be described below.

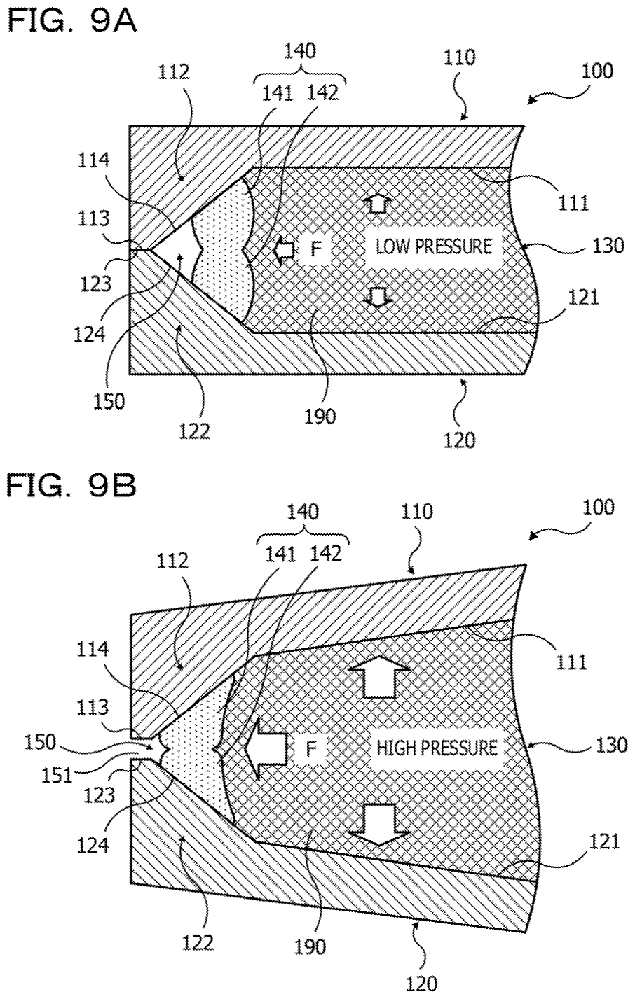

As above-mentioned, in the cooling system (FIG. 2), the refrigerant is circulated through the cooling device 400, the tank 100, and the heat exchanger 200 by the pump 300, whereby cooling of the electronic device 600 is conducted. When the refrigerant is circulated by the pump 300, a comparatively high internal pressure of approximately 0.5 to 1 MPa may be generated in the tank 100. In the tank 100, leakage of the refrigerant stored in the inside 130 thereof is suppressed even when such a comparatively high internal pressure is generated. This point will be described referring to FIG. 9.

FIGS. 9A and 9B are figures illustrating an example of use status of a tank according to the second embodiment. FIG. 9A depicts a sectional schematic view of a major part of an example of the tank when the internal pressure is comparatively low. FIG. 9B depicts a sectional schematic view of a major part of an example of the tank when the internal pressure is comparatively high.

As illustrated in FIG. 9A, of the tank 100, a liquid refrigerant 190 such as an antifreezing fluid is stored in the inside 130 surrounded by the housing 110 and the housing 120 and the elastic body 140. In the tank 100, with the refrigerant 190 stored in the inside 130, forces F acting from inside to outside as indicated by large-width arrows (small) in FIG. 9A. FIG. 9A depicts an example of a state when the forces F is comparatively small, for example, when the pressure (internal pressure) in the inside 130 of the tank 100 is comparatively low.

In a case where the internal pressure of the tank 100 is comparatively low as depicted in FIG. 9A, the refrigerant 190 in the inside 130 is dammed up by the elastic body 140 composed of the elastic body 141 and the elastic body 142 stuck to the peripheral edge section 112 of the housing 110 and the peripheral edge section 122 of the housing 120 and stuck to each other. In the tank 100, when the internal pressure is comparatively low, the elastic body 140 in the stuck state suppresses the refrigerant 190 in the inside 130 from leaking to the space 150 outside the elastic body 140. As a result, the refrigerant 190 is suppressed from leaking to the exterior of the tank 100.

On the other hand, FIG. 9B depicts an example of a state when the pressure (internal pressure) In the inside 130 of the tank 100 is brought to a comparatively high pressure, for example, by the pump 300 that circulates the refrigerant 190 in the above-mentioned manner.

When the internal pressure thus becomes comparatively high, in the tank 100, forces F acting from inside to outside as indicated by large-width arrows (large) In FIG. 9B become comparatively large. In a case where a resin material is used for the housing 110 and the housing 120 of the tank 100, the comparatively large forces F act in the inside 130, whereby the housing 110 and the housing 120 may be pressed open to outer sides and the inside 130 (the volume thereof) may be expanded, as depicted in FIG. 98. When the inside 130 is expanded, a gap 151 may be formed (or the originally present gap 151 may be enlarged) between the projecting end 113 of the peripheral edge section 112 of the housing 110 and the projecting end 123 of the peripheral edge section 122 of the housing 120 (between the parts fastened by the screws 160 or the like), as illustrated in FIG. 9B.

In the tank 100, when the comparatively large forces F act as depicted in FIG. 9B, the elastic body 140 is pressed from inside by the refrigerant 190, and is deformed toward the projecting end 113 of the housing 110 and the projecting end 123 of the housing 120 that face each other. This deformation may be accompanied by a movement (displacement from an initial position) of the elastic body 140 toward the projecting end 113 and the projecting end 123. The elastic body 140 is deformed on the inclined surface 114 of the peripheral edge section 112 and the inclined surface 124 of the peripheral edge section 122 toward the projecting end 113 and the projecting end 123, while the elastic body 141 and the elastic body 142 remain in the stuck state. In the tank 100, both the peripheral edge section 112 of the housing 110 and the peripheral edge section 122 of the housing 120 have the inclined surface 114 and the inclined surface 124 on inside, so that the spacing between the inclined surface 114 and the inclined surface 124 is narrowed in approaching the projecting end 113 and the projecting end 123 which face each other. Therefore, during the deformation of the elastic body 140, the elastic body 141 and the elastic body 142 are not liable to be peeled off from each other, and when the internal pressure of the tank 100 rises, the elastic body 140 is deformed in such a manner as to fill the space 150 surrounded by the elastic body 140 and the inclined surface 114 and the inclined surface 124, while the stuck state is maintained. Since the spacing between the inclined surface 114 and the inclined surface 124 is narrowed in approaching the projecting end 113 and the projecting end 123, the deformation of the elastic body 140 such as to fill the space 150 ensures that the elastic body 141 and the elastic body 142 are stuck to each other more strongly.

In the tank 100, even when the refrigerant 190 in the inside 130 is brought to a comparatively high pressure, the elastic body 140 is deformed such as to fill the space 150 outside thereof while remaining in the stuck state, whereby the sealing property is maintained, and the refrigerant 190 is suppressed from leaking into the space 150. As a result, the refrigerant 190 is suppressed from leaking to the exterior of the tank 100.

In the tank 100, the refrigerant 190 may be brought to a comparatively high pressure, and the inside 130 may be expanded, resulting in the formation of the gap 151 between the housing 110 and the housing 120. In the tank 100, even in the case where the inside 130 is expanded in this way, since the peripheral edge section 112 and the peripheral edge section 122 have the inclined surface 114 and the inclined surface 124 on inside, the spacing therebetween is comparatively suppressed from widening. Even when the elastic body 140 being pushed from inside by the forces F is deformed such as to fill the space 150, the elastic body 141 and the elastic body 142 are not liable to be peeled off, and they remain in the stuck state or are stuck together more strongly. In the tank 100, when the internal pressure is raised, the elastic body 140 is deformed such as to fill the space 150 outside thereof while remaining in the stuck state, whereby the sealing property is maintained, and the refrigerant 190 is suppressed from leaking into the space 150. Further, in the tank 100, even in the case where the inside 130 is expanded due to a rise in the internal pressure and the gap 151 is formed, leakage of the refrigerant 190 into the space 150 outside of the elastic body 140 is suppressed, and, therefore, the refrigerant 190 is suppressed from leaking through the gap 151 to the exterior of the tank 100.

In the tank 100, the gap 151 may be present between the projecting end 113 and the projecting end 123, when the internal pressure thus rises and the inside 130 is expanded, and besides, in a state in which the housing 110 and the housing 120 are fixed by the screws 160 and the nuts 170 when assembled. Also in the case where the gap 151 is thus present originally (from the time of assembly), a rise in the internal pressure of the tank 100 results in deformation of the elastic body 140 such as to fill the space 150 while remaining in a stuck state, so that the sealing property is maintained. As a result, the refrigerant 190 is suppressed from leaking into the space 150, or from leaking through the gap 151 to the exterior.

In the tank 100, when the internal pressure is raised as above-mentioned and is thereafter lowered again, the elastic body 140 having been deformed such as to fill the space 150 may maintain the deformed shape, or may return to a shape before the deformation. In either case, in response to a later rise in the internal pressure, the sealing property is maintained, and leakage of the refrigerant 190 is suppressed. Whether or not the elastic body 140 maintains the deformed shape after the deformation such as to fill the space 150 depends on the pressure of the refrigerant 190 stored in the inside 130, and the properties, for example, magnitude of the sticking property, of the material used for the elastic body 140.

According to the above-described configuration, it is possible to obtain a tank 100 capable of effectively suppressing leakage of a refrigerant 190 stored in the inside 130 thereof.

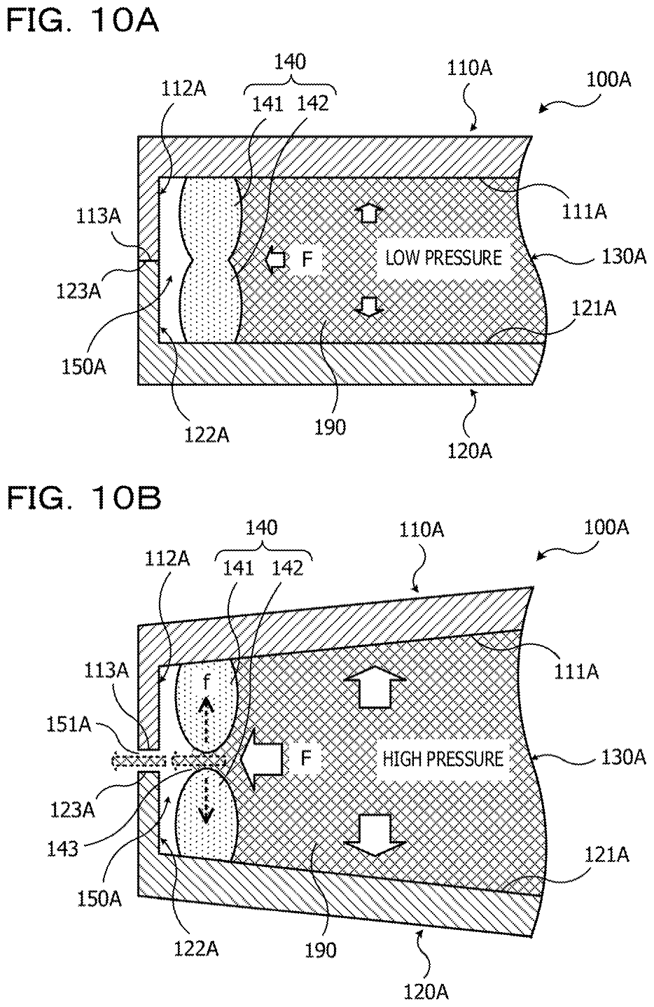

Here, for comparison, a tank in a form in which inclined surfaces are not provided on the inside of peripheral edge sections of housings will be described referring to FIG. 10.

FIGS. 10A and 10B are figures illustrating an example of use status of a tank according to another embodiment. FIG. 10A depicts a sectional schematic view of a major part of an example of the tank when the internal pressure is comparatively low. FIG. 10B depicts a sectional schematic view of a major part of an example of the case when the internal pressure is comparatively high.

FIG. 10A schematically depicts a major part section of a tank 100A in which a housing 110A including an inner surface 111A and a peripheral edge section 112A projecting therefrom and a housing 120A including an inner surface 121A and a peripheral edge section 122A projecting therefrom are made to face each other and are fixed by screwing or the like. In the tank 100A, the peripheral edge section 112A of the housing 110A and the peripheral edge section 122A of the housing 120A are not provided with above-mentioned inclined surface 114 or inclined surface 124, and the peripheral edge section 112A and the peripheral edge section 122A project perpendicularly to the inner surface 111A and the inner surface 121A. The elastic body 140 composed of the elastic body 141 and the elastic body 142 is disposed in a stuck state on the inner surface 111A and the inner surface 121A on the inside of the peripheral edge section 112A and the peripheral edge section 122A. The tank 100A differs from the above-described tank 100 in that it has the just-mentioned configuration.

The liquid refrigerant 190 such as an antifreezing fluid is stored in an inside 130A surrounded by the housing 110A and the housing 120A and the elastic body 140 of the tank 100. In the tank 100A, with the refrigerant 190 stored in the inside 130A, forces F act from inside to inside, as indicated by large-width arrows (small) in FIG. 10A. FIG. 10A depicts an example of a state when the forces F are comparatively small, for example, when the internal pressure of the tank 100A is comparatively low. In a case where the internal pressure of the tank 100A is comparatively low as in FIG. 10A, the refrigerant 190 in the inside 130A is dammed up by the elastic body 140, whereby the refrigerant 190 is suppressed from leaking into a space 150A outside of the elastic body 140, or from leaking to the exterior of the tank 100A.

FIG. 10B depicts an example of a state when the refrigerant 190 is stored in the inside 130A and the internal pressure of the tank 100A is brought to a comparatively high pressure, for example, by the pump 300 for circulating the refrigerant 190 as above-mentioned.

When the internal pressure becomes comparatively high in this way, in the tank 100A, the forces F acting from inside to outside are comparatively enlarged, as indicated by large-width arrows (large) in FIG. 10B. In a case where a resin material is used for the housing 110A and the housing 120A of the tank 100A, the comparatively large forces F act in the inside 130A, whereby the housing 110A and the housing 120A may be pressed open to outer sides and the inside 130A may be expanded, as depicted in FIG. 10B. When the inside 130A is expanded, a gap 151A may be formed (or the originally existing gap 151A may be enlarged) between a projecting end 113A of the peripheral edge section 112A of the housing 110A and a projecting end 123A of the peripheral edge section 122A of the housing 120A (between the parts fastened by screws or the like), as depicted in FIG. 10B.

In the tank 100A, the peripheral edge section 112A of the housing 110A and the peripheral edge section 122A of the housing 120A are not provided with the above-mentioned inclined surface 114 or inclined surface 124. Therefore, in the tank 100A, as the housing 110A and the housing 120A are pressed open to outer sides by the forces F from inside and the inside 130A is expanded, the spacing between the inner surface 111A and the inner surface 121A facing each other in the vicinity of the peripheral edge section 112A and the peripheral edge section 122A is comparatively enlarged. As a result, in the tank 100A, even if the elastic body 140 being pushed by the forces F from inside is deformed toward the projecting end 113A and the projecting end 123A, forces f in directions for peeling off the elastic body 141 and the elastic body 142 which are in a stuck state and forming the elastic body 140 are exerted on the elastic body 140. When such forces f act and if the elastic body 141 and the elastic body 142 in the stuck state and forming the elastic body 140 are peeled off and separated from each other, the refrigerant 190 would leak through a gap 143 formed between the elastic body 141 and the elastic body 142 into the space 150A outside of them. In a case where the housing 110A and the housing 120A are pressed open to outer sides by the forces F and the gap 151A is formed between the projecting end 113A and the projecting end 123A, the refrigerant 190 having leaked into the space 150A would further leak through the gap 151A to the exterior of the tank 100A.

Here, an example has been described in which the elastic body 141 and the elastic body 142 forming the elastic body 140 are peeled off to form the gap 143. Other than this, in the tank 100A, due to the expansion of the inside 130A, the elastic body 141 may be peeled off from the housing 110A to form a gap therebetween, or the elastic body 142 may be peeled off from the housing 120A to form a gap therebetween. Also when such a gap is formed, leakage of the refrigerant 190 similar to the above-mentioned is generated through the gap.

Note that as the elastic body 140, one that is a single body originally may be used, instead of the above-mentioned elastic body 140 obtained by sticking the two members of the elastic body 141 and the elastic body 142. Even when the elastic body 140 as a single body is thus used, however, the expansion of the inside 130A may cause the elastic body 140 to be peeled off from the housing 110A or the housing 120A to form a gap, and leakage of the refrigerant 190 similar to the above-mentioned may be generated through the gap.

In contrast to the tank 100A as depicted in FIGS. 10A and 108, in the tank 100 as illustrated in FIGS. 9A and 9B, the peripheral edge section 112 of the housing 110 and the peripheral edge section 122 of the housing 120 both have the inclined surface 114 and the inclined surface 124 on inside. Therefore, the spacing between the inclined surface 114 and the inclined surface 124 is narrowed in approaching the projecting end 113 and the projecting end 123 facing each other. As a result, even when the elastic body 140 pushed by the forces F from inside is deformed such as to fill the space 150, the elastic body 141 and the elastic body 142 are not liable to be peeled off, but are kept in the stuck state or are stuck more strongly. According to the tank 100 provided with the inclined surface 114 and the inclined surface 124, even when the internal pressure is raised, the elastic body 140 is deformed such as to fill the space 150 outside thereof while remaining in the stuck state, whereby the sealing property is maintained, and the refrigerant 190 is effectively suppressed from leaking into the space 150. Further, the refrigerant 190 is effectively suppressed from leaking through the gap 151 to the exterior of the tank 100.

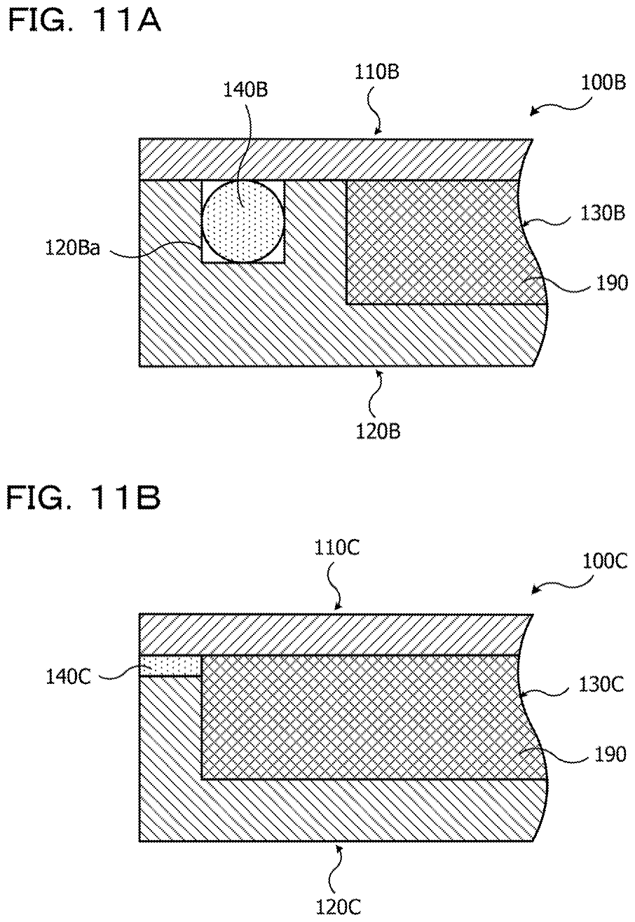

Note that as a form of the tank to be used for the cooling system 1000, there may also be contemplated one as depicted in FIGS. 11A and 11B below.

FIGS. 11A and 11B are figures depicting examples of a tank according to further embodiments. FIG. 11A depicts a sectional schematic view of a major part of an example of a tank in which a seal member is sandwiched between housings. FIG. 11B depicts a sectional schematic view of a major part of an example of a tank in which the housings are adhered to each other by an adhesive.

A tank 100B depicted in FIG. 11A has a configuration in which a seal member 140B such as a seal ring and a rubber packing is interposed between a housing 110B and a housing 120B (a groove 120Ba thereof). The housing 110B and the housing 120B combined together through the seal member 140B are fixed by screwing or the like. The liquid refrigerant 190 such as an antifreezing fluid is stored in an inside 130B of the housing 110B and the housing 120B fixed.

In such a tank 100B, for example, in a case where the housing 110B and the housing 120B are formed using a metallic material, the weight of the tank 100B is increased, making it may not be necessarily easy to assemble the tank 100B or install it in a communication base station or the like. When it is attempted to enlarge the compression amount of the seal member 140B for generating a surface pressure durable to a comparatively high internal pressure, the housing 110B and the housing 120B which are large in size and robust are used, and the tank 100B would therefore be enlarged in size. Enlargement of the tank 100B in size may cause a lowering in space efficiency of the communication base station or the like where to install the tank 100B. In the tank 100B, where the housing 110B and the housing 120B are formed using a resin material, lightening of the tank 100B in weight may be achieved, but a situation may occur in which a rise in the internal pressure would form a gap between the housing 110B and the housing 120B (between the parts fastened by screws or the like), causing leakage.

On the other hand, the tank 100C depicted in FIG. 11B has a configuration in which a housing 110C and a housing 120C are adhered to each other by an adhesive 140C. The housing 110C and the housing 120C adhered to each other by the adhesive 140C are fixed by screwing or the like. The liquid refrigerant 190 such as an antifreezing fluid is stored in an inside 130C of the housing 110C and the housing 120C fixed.

Even in such a tank 100C, in a case where the housing 110C and the housing 120C are formed using a metallic material, the weight of the tank 100C increases, making it may not be necessarily easy to assemble the tank 100C or install it in a communication base station or the like. In the tank 100C, in a case where the housing 110C and the housing 120C are formed using a resin material, lightening of the tank 100C in weight may be achieved, but a rise in the internal pressure may form a gap between the housing 110C and the housing 120C (between the parts fastened by screws or the like), causing leakage. When the adhesive 140C is used, it becomes difficult to dismantle or repair the tank 100C, and the kinds and combination of the materials usable for the adhesive 140C and the housing 110C and the housing 120C may be severely limited.

Other than the above-mentioned tank 100B and tank 100C, there may be contemplated a tank which is obtained by welding together housings formed using a metallic material. Even in such a tank, however, an increase in the weight of the tank may be generated, it becomes difficult to dismantle or repair the tank, and the materials may be limited, similarly to the above.

On the other hand, in the tank 100 depicted in FIGS. 9A and 9B, for example, the housing 110 and the housing 120 are formed using a resin material. The peripheral edge section 112 of the housing 110 and the peripheral edge section 122 of the housing 120 formed using a resin material are provided respectively with the inclined surface 114 and the inclined surface 124. The elastic body 140 (elastic bodies 141 and 142) formed using an extra low hardness thermoplastic resin having a sticking property and a flexible property is disposed on the inside of the peripheral edge section 112 and the peripheral edge section 122. According to such a configuration, the tank 100 is realized in which a sealing property is maintained against a rise in the internal pressure and leakage of the refrigerant 190 stored in the inside 130 to the exterior is effectively suppressed.

In the tank 100, a resin material is used for the housing 110 and the housing 120, whereby lightening in weight is realized. In the tank 100, the above-mentioned compression of the seal member 140B and the use of the large-sized robust housing 110B and housing 120B therefor are not needed, so that a reduction in size is realized. In the tank 100, a resin material is used for the housing 110 and the housing 120, and, even when the gap 151 is formed between the peripheral edge section 112 and the peripheral edge section 122 due to a rise in the internal pressure, the deformation of the elastic body 140 in the stuck state on the inclined surface 114 and the inclined surface 124 maintains a sealing property, and suppresses leakage. In the tank 100, a technique of fixing the housing 110 and the housing 120 by the screws 160 is used, and an elastic body which has a sticking property and may be peeled off is used as the elastic body 140, so that the tank 100 may be easily dismantle by detaching of the screws 160 and peeling of the elastic body 140. In the tank 100, if only the elastic body 140 has a certain sticking property in relation to the housing 110 and the housing 120, it is possible to maintain a sealing property and to suppress leakage of the refrigerant 190. Therefore, various resin materials may be used for the housing 110 and the housing 120, based on the weight thereof, the kind of the refrigerant 190 stored in the inside 130, and so on.

The results of a simulation of a status of the tank 100 in response to a rise in the internal pressure will be described below.

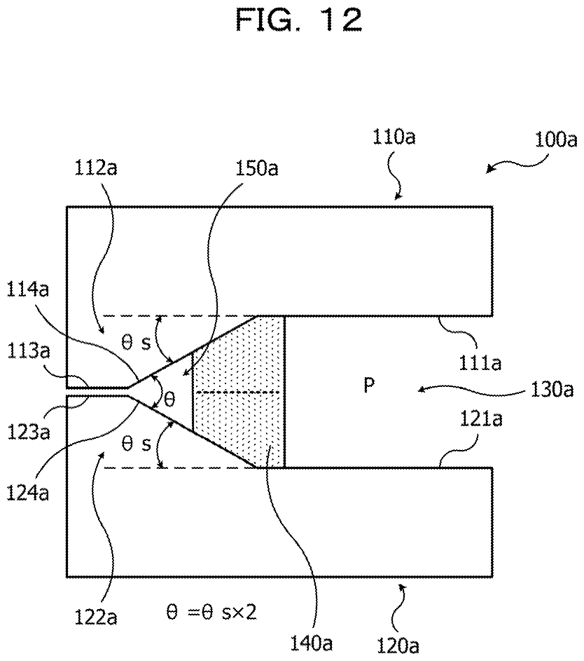

FIG. 12 is a figure illustrating a simulation model of a tank.

For the simulation of the tank 100, a model 100a as depicted in FIG. 12 is used. The model 100a includes a housing 110a and a housing 120a, and an elastic body 140a disposed between them.

The housing 110a includes an inner surface 111a and a peripheral edge section 112a projecting therefrom, and the peripheral edge section 112a is provided on the inside thereof with an inclined surface 114a inclined from inside to outside from the inner surface 111a toward a projecting end 113a. The angle of the inclined surface 114a relative to the inner surface 111a is θs. Similarly, the housing 120a includes an inner surface 121a and a peripheral edge section 122a projecting therefrom, and the peripheral edge section 122a is provided on the inside thereof with an inclined surface 124a inclined from inside to outside from the inner surface 121a toward a projecting end 123a. The angle of the inclined surface 124a relative to the inner surface 121a is θs. In the model 100a as depicted in FIG. 12, the angle θ formed between the inclined surface 114a and the inclined surface 124a is two times the angle θs (θ=θs×2). An elastic body in which two elastic bodies 141 and 142 are stuck to each other (dotted line) and are unified with each other is used as the elastic body 140a. Such an elastic body 140a is disposed on the inside of the peripheral edge section 112a and the peripheral edge section 122a.

In regard of the model 100a as above, a status when the angle θs of the inclined surface 114a and the inclined surface 124a, and the pressure (internal pressure) P in an inside 130a surrounded by the housing 110a and the housing 120a and the elastic body 140a are varied was simulated.

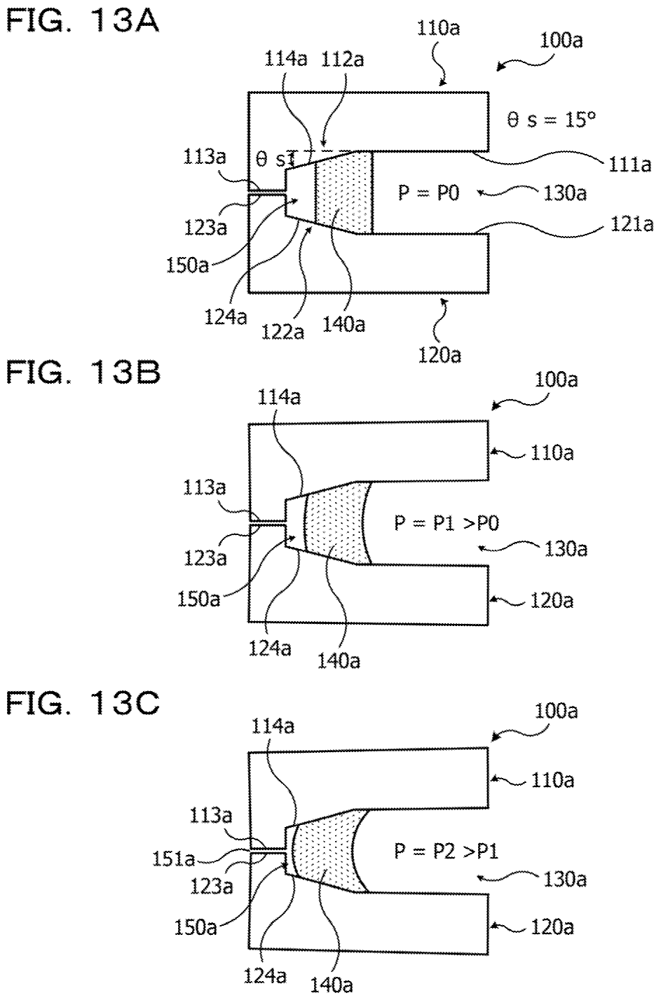

FIGS. 13A to 16C are figures depicting examples of simulation results of tanks, respectively.

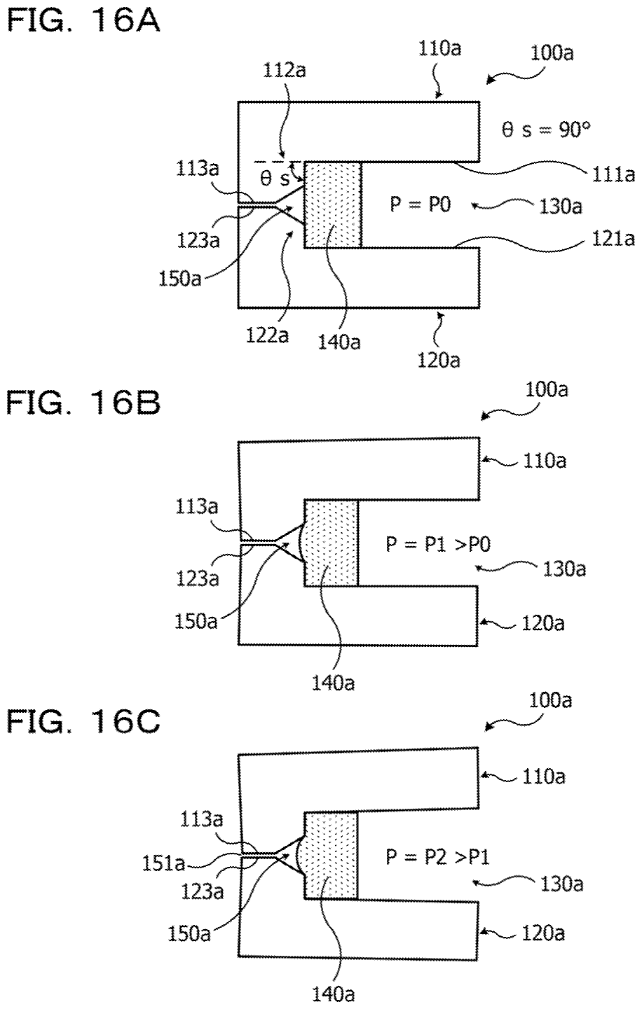

FIGS. 13A to 13C, 14A to 14C, and 15A to 15C depict the simulation results in regard of models 100a in which the angle θs of the inclined surface 114a and the inclined surface 124a is set to 15°, 30°, and 45°, respectively, when an internal pressure P is raised from P0 through P1 (>P0) to P2 (>P1). FIGS. 16A to 16C depict the simulation results in regard of a model 100a in which the peripheral edge section 112a and the peripheral edge section 122a are 90° relative to the inner surface 111a and the inner surface 121a (for convenience of explanation, a model obtained by changing the angle θs of the model 100a to 90°) when the internal pressure P is raised from P0 through P1 to P2.

First, the simulation results illustrated in FIGS. 13A to 13C will be described.

FIGS. 13A to 13C depict an example of the simulation results of a model 100a in which the angle θs of the inclined surface 114a and the inclined surface 124a is 15°. In the case where θs=15°, when the internal pressure P rises from the initial P0 (FIG. 13A) to P1 (FIG. 13B) higher than P0, the elastic body 140a is pressed from inside, and is deformed toward the space 150a outside of the elastic body 140a. When the internal pressure P rises from P1 (FIG. 13B) to P2 (FIG. 13C) higher than P1, the elastic body 140a is further strongly pressed from inside to deform toward the space 150a, thereby further filling the space 150a. Where θs=15°, as the internal pressure P rises to P1 and to P2, the elastic body 140a is deformed along the inclined surface 114a and the inclined surface 124a, and shows an effect to sufficiently fill the space 150a. Thus, attendant on a rise in the internal pressure P, the elastic body 140a is deformed in such a manner as to fill the space 150a, whereby a sealing property for the inside 130a is maintained, and leakage of the refrigerant stored is suppressed. Even when the inside 130a is expanded and, further, the gap 151a is formed between the projecting end 113a and the projecting end 123a, the sealing property for the inside 130a is maintained, and leakage of the refrigerant stored is suppressed.

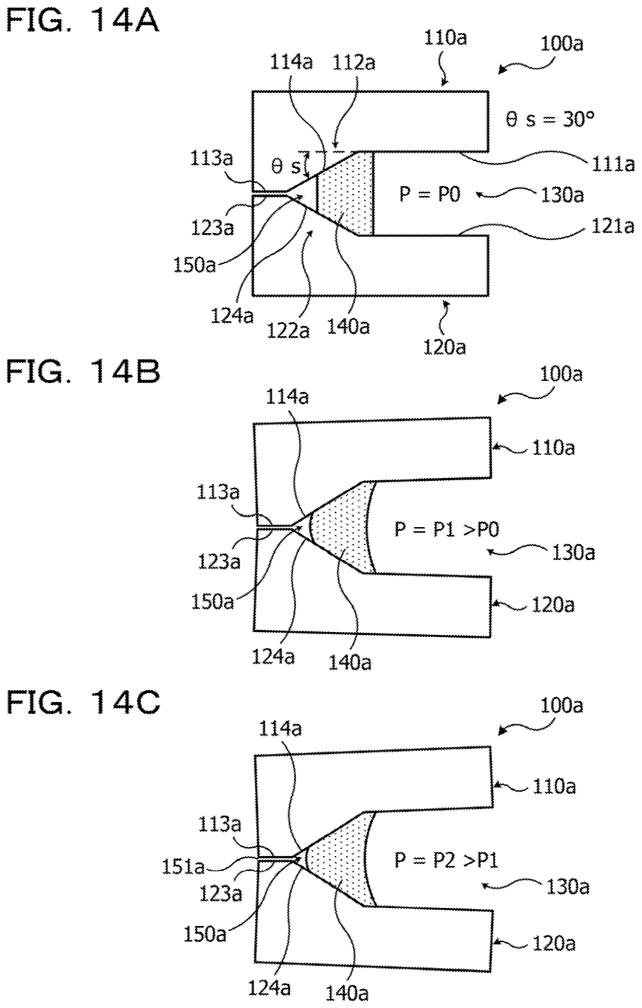

The simulation results depicted in FIGS. 14A to 14C will now be described.

FIGS. 14A to 14C are figures depicting an example of simulation results of a model 100a in which the angle θs of the inclined surface 114a and the inclined surface 124a is 30°. In the case where θs=30°, also, when the internal pressure P rises from the initial P0 (FIG. 14A) to P1 (FIG. 14B) higher than P0, the elastic body 140 is pressed from inside, and is deformed toward the space 150a. When the internal pressure P rises from P1 (FIG. 14B) to P2 (FIG. 14C) higher than P1, the elastic body 140a is further strongly pressed from inside and deformed toward the space 150a, thereby further filling the space 150a. Where θs=30°, attendant on the rise of the internal pressure P to P1 and to P2, the elastic body 140a is deformed along the inclined surface 114a and the inclined surface 124a, showing an effect to sufficiently fill the space 150a to the vicinity of the projecting end 113a and the projecting end 123a. The deformation of the elastic body 140a such as to fill the space 150a attendant on the rise in the internal pressure P maintains a sealing property for the inside 130a, and suppresses leakage of the refrigerant stored. Even when the inside 130a is expanded and the gap 151a is formed between the projecting end 113a and the projecting end 123a, the sealing property for the inside 130a is maintained, and leakage of the refrigerant stored is suppressed.

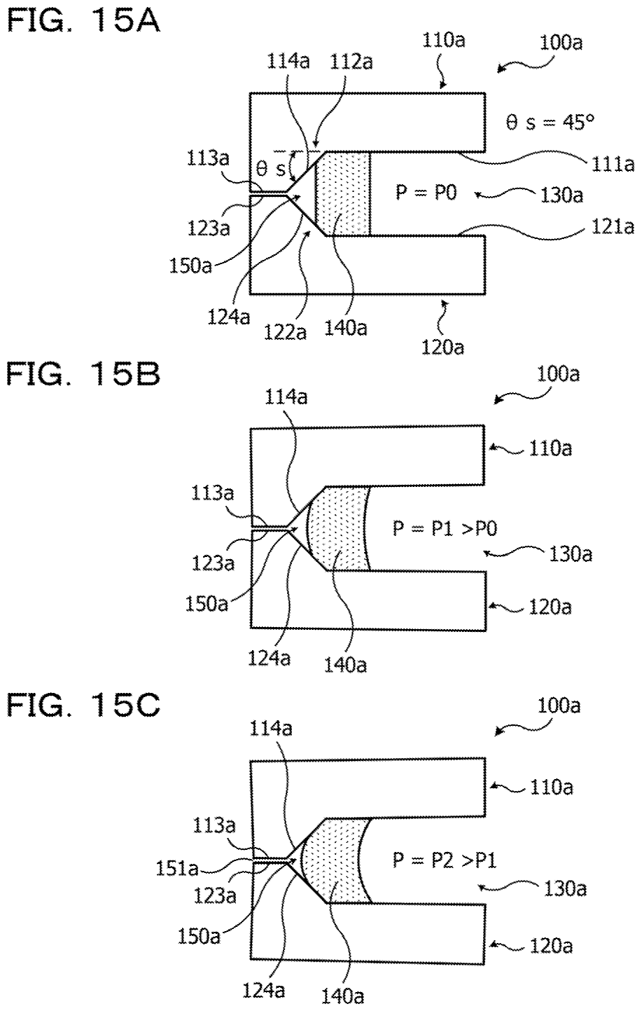

The simulation results depicted in FIGS. 15A to 15C will now be described.

FIGS. 15A to 15C are figures depicting an example of simulation results of a model 100a in which the angle θs of the inclined surface 114a and the inclined surface 124a is 45°. In the case where θs=45°, also, when the internal pressure P rises from the initial P0 (FIG. 15A) to P1 (FIG. 15B) higher than P0, the elastic body 140a is pressed from inside and deformed toward the space 150a. When the internal pressure P rises from P1 (FIG. 15B) to P2 (FIG. 15C) higher than P1, the elastic body 140a is more strongly pressed from inside and deformed toward the space 150a, thereby further filling the space 150a. Where θs=45°, attendant on the rise of the internal pressure P to P1 and to P2, the elastic body 140a is deformed along the inclined surface 114a and the inclined surface 124a, showing an effect to sufficiently fill the space 150a to the vicinity of the projecting end 113a and the projecting end 123a. The deformation of the elastic body 140a such as to fill the space 150a attendant on the rise in the internal pressure P maintains a sealing property for the inside 130a, and suppresses leakage of the refrigerant stored. Even when the inside 130a is expanded and the gap 151a is formed between the projecting end 113a and the projecting end 123a, the sealing property for the inside 130a is maintained, and leakage of the refrigerant stored is suppressed.

The simulation results depicted in FIGS. 16A to 16C will now be described.

FIGS. 16A to 16C are figures depicting an example of simulation results of a model 100a in which the angle θs is 90°. In the case where s=90°, when the internal pressure P rises from the initial P0 (FIG. 16A) to P1 (FIG. 168) higher than P0, the elastic body 140a is pressed from inside and slightly deformed toward the space 150a. When the internal pressure P rises from P1 (FIG. 16B) to P2 (FIG. 16C) higher than P1, the elastic body 140a is deformed toward the space 150a, though only slightly. Where θs=90°, the peripheral edge section 112a and the peripheral edge section 122a appearing as vertical walls in relation to the inner surface 111a and the inner surface 121a suppress the deformation of the elastic body 140a attendant on the increase in the internal pressure P, and reduce the effect to fill the space 150a. Therefore, when the inside 130a is expanded attendant on the rise in the internal pressure P, splitting of the two members forming the elastic body 140a or the formation of the gap between the elastic body 140a and the inner surface 111a or the inner surface 121a, like the above description referring to FIG. 10B, may occur, depending on the expansion amount.

Therefore, in the tank 100, it is desirable that the peripheral edge section 112 of the housing 110 and the peripheral edge section 122 of the housing 120 are provided on the inside thereof with the inclined surface 114a and the inclined surface 124a (surfaces inclined at an angle of less than 90 relative to the inner surface 111a and the inner surface 121a), respectively.

A case where the liquid refrigerant 190 such as an antifreezing fluid is used as the refrigerant in the cooling system 1000 and such a refrigerant 190 is stored in the inside 130 of the tank 100 has been taken as an example in the above description. Other than this, a gaseous refrigerant may be used for the cooling system 1000, and such a gaseous refrigerant may be stored in the inside 130 of the tank 100. In the case where a gaseous refrigerant is thus stored in the inside 130 of the tank 100, also, a similar effect to the above-mentioned may be obtained. Even when the internal pressure rises and even when the inside 130 is expanded due to a rise in the internal pressure and the gap 151 is formed between the projecting end 113 and the projecting end 123, the elastic body 140 is deformed in such a manner as to fill the space 150 outside thereof while remaining in the stuck state. As a result, the sealing property for the inside 130 is maintained, and leakage of the gaseous refrigerant stored is suppressed.

The tank 100 configured as above-described is applicable as a tank for storing various substances, not limited to a refrigerant. The tank 100 is applicable to, in addition to the cooling system 1000, various production lines including a process of storing a given substance.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A tank comprising:
a first housing configured to include a first inner surface and a first peripheral edge section projecting from the first inner surface;
a second housing configured to include a second inner surface and a second peripheral edge section, the second inner surface facing the first inner surface, the second peripheral edge section projecting from the second inner surface and facing the first peripheral edge section; and
a sticky elastic body provided inside the first peripheral edge section and the second peripheral edge section facing each other,
wherein the first peripheral edge section has a first inclined surface that is inclined from inside to outside from the first inner surface toward a first projecting end of the first peripheral edge section,
the second peripheral edge section has a second inclined surface that is inclined from inside to outside from the second inner surface toward a second projecting end of the second peripheral edge section, and
the elastic body is stuck to the first inclined surface and the second inclined surface.

2. The tank according to claim 1, wherein a material that is deformed to a side of the first projecting end and the second projecting end facing each other in a state of being stuck to the first inclined surface and the second inclined surface by a pressure in an inside surrounded by the first housing, the second housing, and the elastic body when the pressure rises is used for the elastic body.

3. The tank according to claim 1, wherein a thermoplastic resin is used for the elastic body.

4. The tank according to claim 1, wherein the elastic body includes a first section stuck to the first inclined surface, and a second section stuck to the second inclined surface and the first section.

5. The tank according to claim 1, wherein a material that is deformed by a pressure in an inside surrounded by the first housing, the second housing, and the elastic body in such a manner that the inside expands when the pressure rises is used for the first housing and the second housing.

6. The tank according to claim 1, wherein a resin material or a resin material including a resin and fibers contained in the resin is used for the first housing and the second housing.

7. The tank according to claim 1, comprising:
a fixing section that fixes the first housing and the second housing in a state in which the first peripheral edge section and the second peripheral edge section face each other.

8. The tank according to claim 1, having a gap between the first projecting end and the second projecting end.

9. A cooling system comprising:
a cooling device into and from which a refrigerant for cooling an electronic device is introduced and discharged;
a tank into, in and from which the refrigerant discharged from the cooling device is introduced, stored, and discharged;
a heat exchanger into, in and from which the refrigerant discharged from the tank is introduced, cooled, and discharged; and
a pump that sends the refrigerant discharged from the heat exchanger to the cooling device,
wherein the tank includes
a first housing configured to include a first inner surface and a first peripheral edge section projecting from the first inner surface,
a second housing configured to include a second inner surface and a second peripheral edge section, the second inner surface facing the first inner surface, the second peripheral edge section projecting from the second inner surface and facing the first peripheral edge section, and
a sticky elastic body provided inside the first peripheral edge section and the second peripheral edge section facing each other,
the first peripheral edge section having a first inclined surface that is inclined from inside to outside from the first inner surface toward a first projecting end of the first peripheral edge section,
the second peripheral edge section having a second inclined surface that is inclined from inside to outside from the second inner surface toward a second projecting end of the second peripheral edge section,
the elastic body being stuck to the first inclined surface and the second inclined surface, and
the refrigerant being stored in the inside surrounded by the first housing, the second housing, and the elastic body.
